(19) United States
(12) Patent Application Publication
(10) Pub. No.: US 2021/0135020 A1
(43) Pub. Date: May 6, 2021

(54) DETECTION PANEL, MANUFACTURING METHOD THEREOF AND DETECTION DEVICE

(71) Applicants: Beijing BOE Sensor Technology Co., Ltd., Beijing (CN); BOE Technology Group Co., Ltd., Beijing (CN)

(72) Inventors: Bin ZHAO, Beijing (CN); Shuai XU, Beijing (CN); Xiaona XU, Beijing (CN)

(73) Assignees: Beijing BOE Sensor Technology Co., Ltd.; BOE Technology Group Co., Ltd.

(21) Appl. No.: 16/846,546

(22) Filed: Apr. 13, 2020

(30) Foreign Application Priority Data
Oct. 31, 2019 (CN) 201911056697.3

(51) Int. Cl. H01L 31/02; H01L 31/0224; H01L 31/0352; H01L 31/08; H01L 31/18

(52) U.S. Cl. CPC H01L 31/02005; H01L 31/022475; H01L 31/1884; H01L 31/085; H01L 31/03529

(57) ABSTRACT

A detection panel, a manufacturing method thereof, and a detection device are provided. The detection panel includes base substrate; a detection circuit on the base substrate; a photoelectric conversion structure on the detection circuit and electrically connected to the detection circuit; and a bias voltage layer on the photoelectric conversion structure and electrically connected to the photoelectric conversion structure; wherein the bias voltage layer has a grid-like structure.

### CROSS-REFERENCES TO RELATED APPLICATION

This application claims priority to Chinese patent application No. 201911056697.3 filed on Oct. 31, 2019, which is incorporated herein by reference in its entirety.

### FIELD

The present disclosure relates to the technical field of detection panels, and particularly to a detection panel, a manufacturing method thereof and a detection device.

### BACKGROUND

A Flat X-ray Panel Detector (FPXD) manufactured on the basis of a Thin Film Transistor (TFT) technique is an essential element in the digital image technique. Due to its fast imaging speed, favorable space and density resolution, high signal to noise ratio, direct digital output and other advantages, it has been widely applied in fields like medical imaging (e.g. Chest X-rays), industrial detection (e.g. metal flaw detection), security detection and air transport.

### SUMMARY

In one aspect, an embodiment of the present disclosure provides a detection panel. The detection panel includes a base substrate, a detection circuit on the base substrate, a photoelectric conversion structure on the detection circuit and electrically connected to the detection circuit, and a bias voltage layer on the photoelectric conversion structure and electrically connected to the photoelectric conversion structure; wherein the bias voltage layer has a grid-like structure.

Optionally, in an implementation, in the detection panel provided by an embodiment of the present disclosure, a material of the bias voltage layer is a transparent conductive material.

Optionally, in an implementation, in the detection panel provided by an embodiment of the present disclosure, the transparent conductive material is ITO.

Optionally, in an implementation, the detection panel provided by an embodiment of the present disclosure further includes a buffer layer between the bias voltage layer and the photoelectric conversion structure and covering the photoelectric conversion structure, and a resin layer between the buffer layer and the bias voltage layer and in contact with the bias voltage layer.

Optionally, in an implementation, the detection panel provided by an embodiment of the present disclosure further includes a scintillator layer on the bias voltage layer, wherein the scintillator layer is in direct contact with the resin layer through openings of the grid-like structure.

Optionally, in an implementation, in the detection panel provided by an embodiment of the present disclosure, the photoelectric conversion structure includes a first electrode, a photodiode and a second electrode stacked successively on the detection circuit, the detection circuit includes a thin film transistor, the first electrode is electrically connected to a drain of the thin film transistor and the second electrode is electrically connected to the bias voltage layer.

In another aspect, an embodiment of the present disclosure further provides a detection device, including the detection panel of any one of the above provided by the embodiment of the present disclosure.

In further aspect, an embodiment of the present disclosure further provides a manufacturing method of the detection panel. The manufacturing method includes: forming a detection circuit on a base substrate; forming a photoelectric conversion structure on the detection circuit; and forming a bias voltage layer on the photoelectric conversion structure, wherein the bias voltage layer is electrically connected to the photoelectric conversion structure, and the bias voltage layer has a grid-like structure.

Optionally, in an implementation, the manufacturing method provided by an embodiment of the present disclosure, before forming the bias voltage layer, further includes: forming a buffer layer covering the photoelectric conversion structure; and forming a resin layer on the buffer layer, wherein the resin layer is in contact with the bias voltage layer.

Optionally, in an implementation, the manufacturing method provided by an embodiment of the present disclosure, after forming the bias voltage layer, further includes: forming a scintillator layer on the bias voltage layer, wherein the scintillator layer is in direct contact with the resin layer through openings of the grid-like structure.

### BRIEF DESCRIPTION OF THE DRAWINGS

FIG. 1 is a schematic structural diagram of a detection panel in related art;

FIG. 2 is a schematic structural diagram of a detection panel provided by an embodiment of the present disclosure;

FIG. 3 is a top view of the detection panel shown in FIG. 2;

FIG. 4 is a schematic diagram of a scintillator layer peeling off phenomenon;

FIG. 5 is a first flow chart of a manufacturing method of a detection panel provided by an embodiment of the present disclosure;

FIG. 6 is a second flow chart of a manufacturing method of a detection panel provided by an embodiment of the present disclosure;

FIG. 7 is a third flow chart of a manufacturing method of a detection panel provided by an embodiment of the present disclosure; and

FIGS. 8A to 8D are respectively a cross-section structural diagram of a detection panel provided by an embodiment of the present disclosure after performing each step.

### DETAILED DESCRIPTION

In order to make the objects, technical solutions and advantages of the present disclosure clearer, implementations of a detection panel, a manufacturing method thereof and a detection device provided by the embodiments of the present disclosure are described in detail below in combination with accompanying drawings.

The thickness and shape of each film layer in the accompanying drawings are only intended to schematically describe the content of the disclosure, rather than to reflect the true proportion of the detection panel.

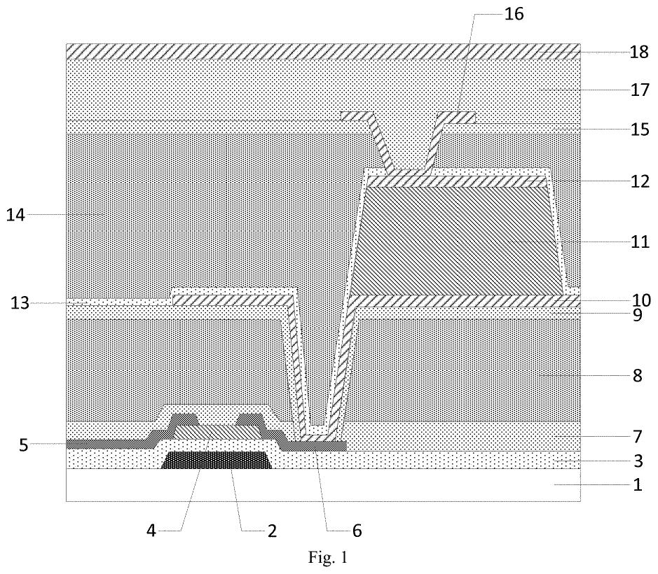

The structure of a detection panel in related art is shown in FIG. 1. The detection panel includes: a base substrate 1, a gate 2 on the base substrate 1, a gate insulating layer 3 located on the gate 2, an active layer 4 located on the gate insulating layer 3, a drain 6 and a source 5s located on the active layer 4 and in a same layer, a first passivation layer 7 located on the drain 6 and the source 5, a first resin layer 8 located on the first passivation layer 7, a second passivation layer 9 located on the first resin layer 8, a first electrode layer 10 located on the second passivation layer 9 and electrically connected to the drain 6, a photodiode 11 located on the first electrode layer 10, a second electrode layer 12 located on the photodiode 11, a buffer layer 13 located on the second electrode layer 12, a second resin layer 14 located on the buffer layer 13, a third passivation layer 15 located on the second resin layer 14, a bias voltage layer 16 located on the third passivation layer 15 and electrically connected to the photodiode 11 by via holes penetrating through the third passivation layer 15 and the second resin layer 14, a fourth passivation layer 17 located on the bias voltage layer 16, an ITO layer 18 located at a binding area and a scintillator layer located on the ITO layer 18 (not shown in FIG. 1).

The detection panel shown in FIG. 1 is liable to cause static electricity to gather on the surface of the detection panel when the test member touches the surface of the detection panel or due to incomplete cleaning process of the detection panel, thereby causing the problem of poor contact due to the accumulation of static electricity on the surface of the detection panel.

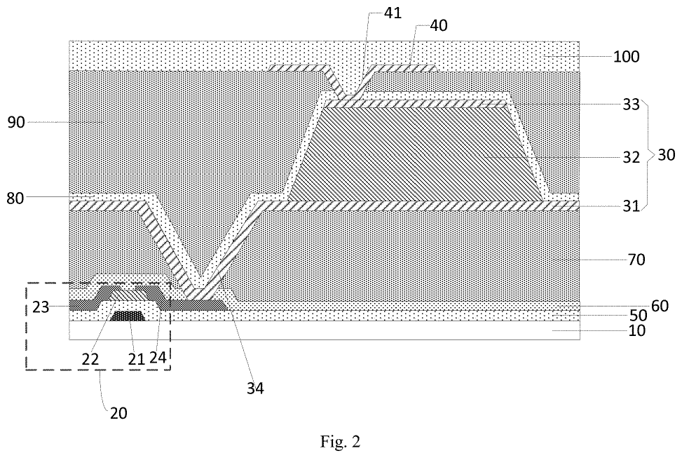

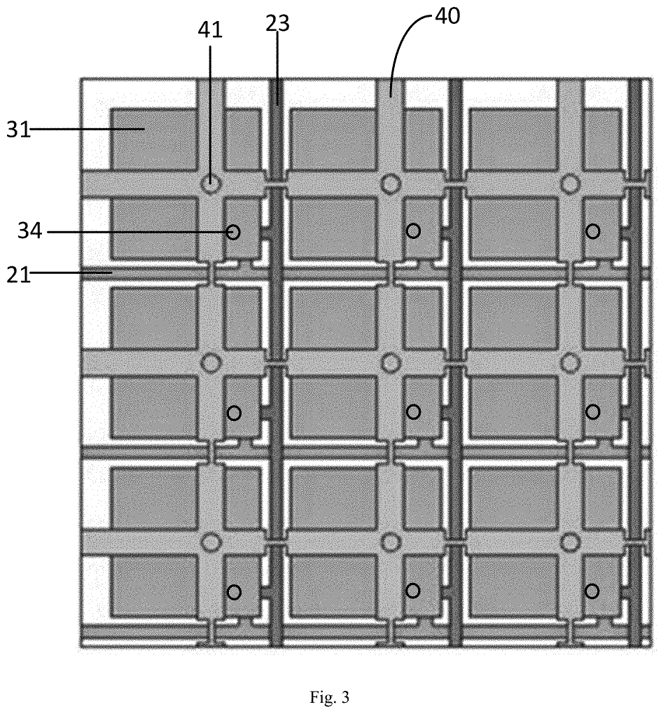

In view of this, the embodiment of the present disclosure provides a detection panel, as shown in FIG. 2 and FIG. 3. FIG. 2 is a schematic cross-section structural diagram of the detection panel provided by the present disclosure and FIG. 3 is a top view of a part of the structure shown in FIG. 2. The detection panel includes a base substrate 10, a detection circuit 20 located on the base substrate 10, a photoelectric conversion structure 30 located on the detection circuit 20 and electrically connected to the detection circuit 20, and a bias voltage layer 40 located on the photoelectric conversion structure 30 and electrically connected to the photoelectric conversion structure 30; the bias voltage layer 40 having a grid-like structure.

The above detection panel provided by the embodiment of the present disclosure includes the base substrate 10, the detection circuit 20 on the base substrate 10, the photoelectric conversion structure 30 on the detection circuit 20 and electrically connected to the detection circuit 20, and the bias voltage layer 40 on the photoelectric conversion structure 30 and electrically connected to the photoelectric conversion structure 30; the bias voltage layer 40 having the grid-like structure. In the present disclosure, the bias voltage layer 40 is set into the grid-like structure. When gathering of static electricity on a surface of the detection panel is caused by touching the surface of the detection panel by a detector or an incomplete washing process of the detection panel, the bias voltage layer 40 of the grid-like structure can lead the static electricity out timely, so as to avoid gathering of the static electricity on a certain place of the surface of the detection panel, improve capability of the detection panel against ESD and reduce Mura resulting from static electricity, thus the problem of poor contact on the surface of the detection panel caused by electrostatic accumulation is improved and the detection panel is protected from being damaged by the static electricity.

In some embodiments, in the above detection panel provided by the present disclosure, as shown in FIG. 2, the detection circuit 20 includes a thin film transistor including a gate 21, an active layer 22, a source 23 and a drain 24 stacked successively on the base substrate 10; a material of the active layer 22 can be amorphous silicon, polysilicon, IGZO and other semiconductor materials, the source 23 and the drain 24 are configured to transmit electrical signals of a data line and a pixel electrode. The detection panel further includes a gate insulating layer 50 located between the gate 21 and the active layer 22, a passivation layer 60 located between the source-drain (23, 24) and the photoelectric conversion structure 30, and a protection layer 70 located between the passivation layer 60 and the photoelectric conversion structure 30, a material of the protection layer 70 can be a resin material, and the protection layer 70 is configured to protect the active layer 22, so as to prevent water vapor in transport from influencing performance of the active layer 22.

In some embodiments, in the above detection panel provided by the present disclosure, as shown in FIG. 2, the photoelectric conversion structure 30 includes a first electrode 31, a photodiode 32 and a second electrode 33 stacked successively on the base substrate 10, the first electrode 31 is electrically connected to the drain 24 of the thin film transistor and the second electrode 33 is electrically connected to the bias voltage layer 40. The passivation layer 60 and the protection layer 70 are provided with a first via hole 34 penetrating through the passivation layer 60 and the protection layer 70, and the first electrode is electrically connected to the drain 24 of the thin film transistor through the first via hole 34. The first electrode 31 is configured to transmit an electrical signal formed after the photodiode 32 is lighted. During work, for example, applying voltage of −5V to −10V to the second electrode 33 makes the photodiode 32 work at a negative bias voltage, thereby making the photodiode 32 generate different electrical signals, which are stored in the first electrode 31. The electrical signals stored in the first electrode 31 are transmitted to an external IC through the detection circuit 20 to store image data.

In some embodiments, in the above detection panel provided by the present disclosure, the photodiode is a PIN photodiode. Specifically, the PIN photodiode includes a P-type area, an N-type area, and an intrinsic area between the P-type area and the N-type area, which are stacked on the base substrate.

In some embodiments, in the above detection panel provided by the present disclosure, as shown in FIG. 3 which shows a top view of a film layer where the gate 21 is located, a film layer where the source-drain (23, 24) are located, a film layer where the first electrode 31 is located and a film layer where the bias voltage layer 40 is located, FIG. 3 mainly aims to schematically describe the bias voltage layer 40 having a grid-like structure, so as to lead static electricity out timely to avoid gathering of the static electricity on a surface of the detection panel, improve capability of the detection panel against ESD and reduce Mura resulting from the static electricity, such that the problem of poor contact on the surface of the detection panel caused by electrostatic accumulation is improved.

In some embodiments, in the above detection panel provided by the present disclosure, as shown in FIG. 2, in order to increase a photoconversion area of the photodiode 32 and improve sensitivity, a material of the bias voltage layer 40 can be a transparent conductive material.

In some embodiments, in the above detection panel provided by the present disclosure, as shown in FIG. 2, a material of the second electrode 33 is a transparent conductive material.

In some embodiments, in the above detection panel provided by the present disclosure, the transparent conductive material may be ITO. Of course, in an implementation, the transparent conductive material is not limited to the ITO and it can also be other transparent conductive materials.

In some embodiments, the above detection panel provided by the present disclosure, as shown in FIG. 2, further includes a buffer layer 80 located between the bias voltage layer 40 and the photoelectric conversion structure 30 and covering the photoelectric conversion structure 30, and a resin layer 90 located between the buffer layer 80 and the bias voltage layer 40 and contacted with the bias voltage layer 40. Specifically, the buffer layer 80 can increase bonding force of the resin layer 90 with the substrate. The second via hole 41 penetrates through the buffer layer 80 and the resin layer 90, and the bias voltage layer 40 is electrically connected to the second electrode 33 through the second via hole 41. In addition, since the material of the bias voltage layer 40 in the detection panel provided by the present disclosure is a transparent conductive material, thus the third passivation layer 15 and the fourth passivation layer 17 are not required to be disposed between the bias voltage layer 40 and the resin layer 90 as FIG. 1 in related art. In the related art as in FIG. 1, the material of the bias voltage layer 16 is metal, and shrinking deformation occurs to the resin layer 90, thereby causing wire breaking of a metal layer. Therefore, it is required to set passivation layers at two sides of the metal layer to isolate contact of the metal layer with the resin layer. Therefore, in the embodiment of the present disclosure, the material of the bias voltage layer 40 is the transparent conductive material, which can save the process and cost for manufacturing the passivation layers at two sides of the bias voltage layer 40. Further since the material of the bias voltage layer 40 is the transparent conductive material such as the ITO, thus the ITO layer at the bonding area of the detection panel and the bias voltage layer 40 are disposed in a same layer, so as to further reduce the arrangement of the ITO layer at the bonding area and further lower the manufacturing process and cost.

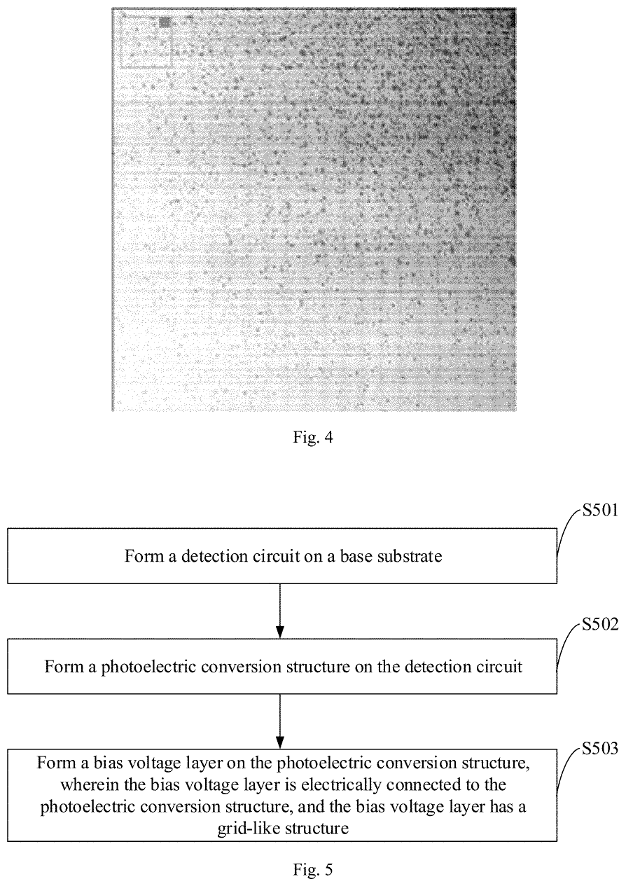

In some embodiments, in an implementation, as shown in FIG. 2, the above detection panel further includes a scintillator layer 100 located on the bias voltage layer 40, the scintillator layer 100 is in direct contact with the resin layer 90 through openings of the grid-like structure. Specifically, in the embodiment of the present disclosure, since the bias voltage layer 40 is in direct contact with the resin layer 90 and the resin layer 90 does not have a passivation layer at one side thereof away from the bias voltage layer 40, thus the scintillator layer 100 is in direct contact with the resin layer. The scintillator layer in related art such as FIG. 1 is in direct contact with the passivation layer. Since the bonding force between the passivation layer and the scintillator layer is weak, it is easy to cause the scintillator layer to peel off in a detection process, as shown in FIG. 4. FIG. 4 shows image data detected when the scintillator layer peels off in related art. In FIG. 4, a black point position is a scintillator layer peeling off phenomenon. Since strength of the attaching force between the resin layer 90 and the scintillator layer 100 is greater than strength of the attaching force between the passivation layer and the scintillator layer 100, thus the detection panel provided by the present disclosure can increase bonding force between the scintillator layer 100 and the substrate, to prevent the scintillator layer 100 from peeling off, thus not producing the problem of the delami defection.

In some embodiments, the scintillator layer is configured to convert a radiation signal into an optical signal and any proper scintillation material can be used to manufacture the scintillator layer. In some embodiments, a scintillation material is an optical wavelength conversion material that converts radiation (e.g. X-ray) into visible light. The scintillation material includes, but not limited to cesium iodide activated by thallium and cesium iodide activated by sodium. The cesium iodide is a light-sensitive material.

In some embodiments, a material of the resin layer has a higher light transmission rate, which is generally greater than 90%. Moreover, the resin layer is manufactured with simple process and can be formed a required pattern directly after exposure and development.

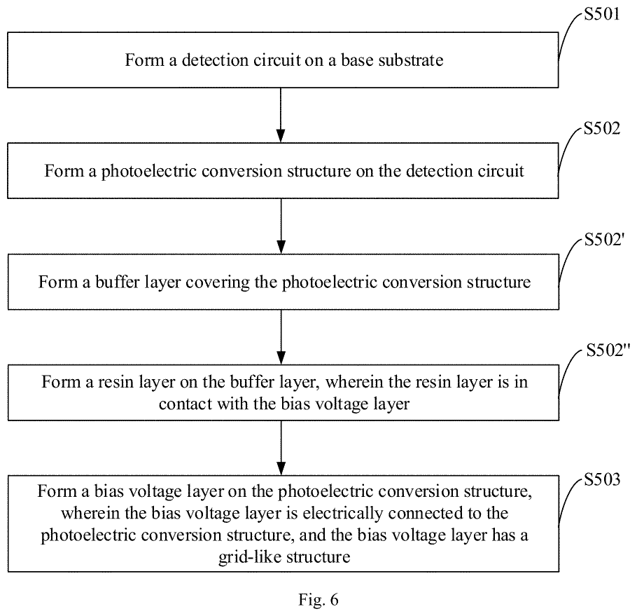

Based on the same inventive concept, the embodiment of the present disclosure further provides a manufacturing method of a detection panel. As shown in FIG. 5, the method includes the following steps.

S501: forming a detection circuit on a base substrate.

S502: forming a photoelectric conversion structure on the detection circuit.

S503: forming a bias voltage layer on the photoelectric conversion structure, wherein the bias voltage layer is electrically connected to the photoelectric conversion structure; wherein the bias voltage layer has a grid-like structure.

The manufacturing method of the detection panel provided by the embodiment of the present disclosure arranges the bias voltage layer into a grid-like structure. When gathering of static electricity on a surface of the detection panel is caused by touching the surface of the detection panel by a detector or an incomplete washing process of the detection panel, the bias voltage layer of the grid-like structure can lead the static electricity out timely, so as to avoid gathering of the static electricity on the surface of the detection panel, improve capability of the detection panel against ESD and reduce Mura resulting from the static electricity, such that the problem of poor contact on the surface of the detection panel caused by electrostatic accumulation is improved.

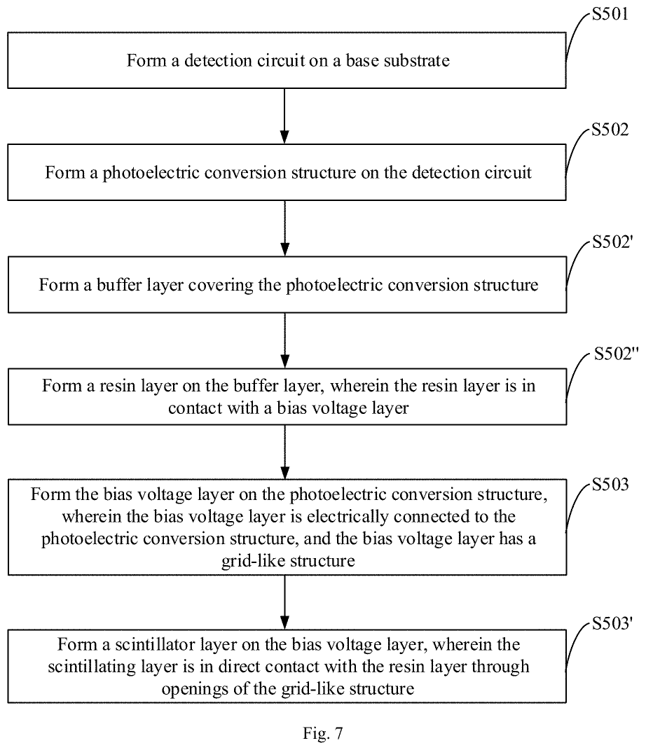

In some embodiments, in the manufacturing method of the above detection panel provided by the present disclosure, as shown in FIG. 6, before forming the bias voltage layer, the method further includes the following steps.

S502′: forming a buffer layer covering the photoelectric conversion structure.

step S502″: forming a resin layer on the buffer layer, wherein the resin layer contact is in contact with the bias voltage layer.

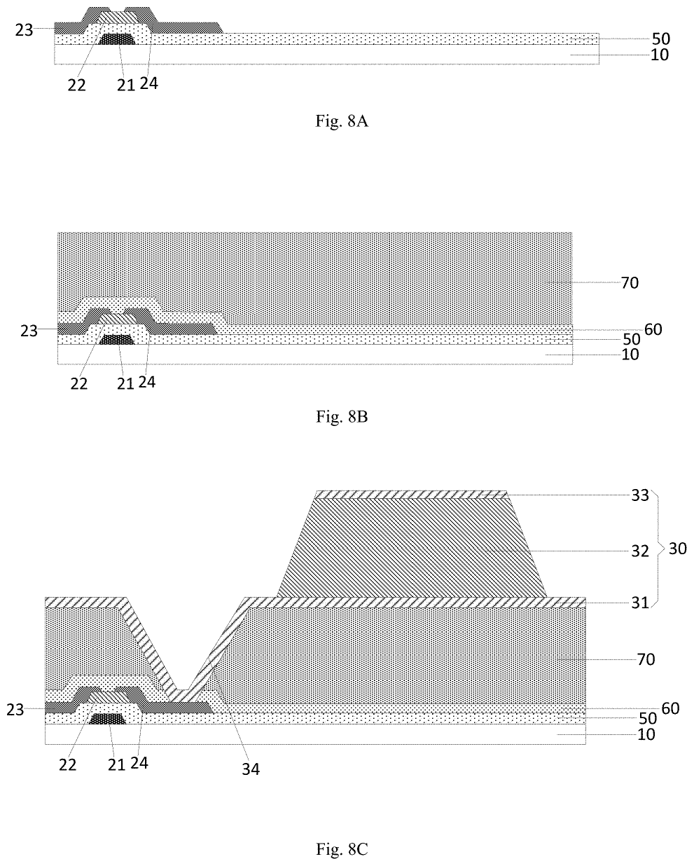

In some embodiments, in the manufacturing method of the above detection panel provided by the present disclosure, as shown in FIG. 7, after forming the bias voltage layer, the method further includes the following steps.

S503′: forming a scintillator layer on the bias voltage layer, wherein the scintillator layer is in direct contact with the resin layer through openings of the grid-like structure.

The manufacturing method of the detection panel shown in FIG. 2 is described in details below through specific embodiments.

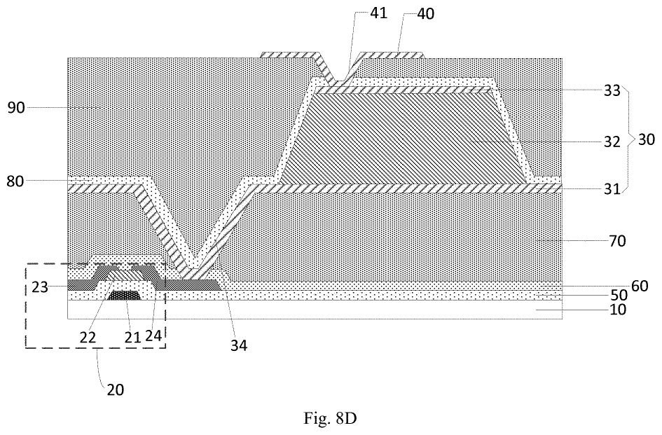

(1) A detection circuit 20 is formed on a base substrate 10. Specifically, a gate 21, a gate insulating layer 50, an active layer 22, a source 23 and a drain 24 are formed successively on the base substrate 10, as shown in FIG. 8A.

(2) A passivation layer 60 and a protection layer 70 are formed on the base substrate 10 with the detection circuit 20 formed, as shown in FIG. 8B.

(3) A photoelectric conversion structure 30 is formed on the base substrate 10 where the protection layer 70 is formed. Specifically, a first electrode 31, a photodiode 32 and a second electrode 33 are formed successively on the base substrate 10 with the protection layer 70 formed, wherein the first electrode 31 is electrically connected to the drain 24 by via holes 34 penetrating through the protection layer 70 and the passivation layer 60, as shown in FIG. 8C.

(4) A buffer layer 80, a resin layer 90 and a bias voltage layer 40 are formed on the base substrate 10 with the photoelectric conversion structure 30 formed, the bias voltage layer 40 is electrically connected to the second electrode 33 by via holes 41 penetrating through the resin layer 90 and the buffer layer 80, and the bias voltage layer 40 has a grid-like structure, as shown in FIG. 8D.

(5) A scintillator layer 100 is formed on the base substrate 10 with the bias voltage layer 40 formed, and the scintillator layer 100 is in direct contact with the resin layer 90, as shown in FIG. 2.

After steps (1) to (5) in the above embodiment, the detection panel provided by the embodiment of the present disclosure and shown in FIG. 2 can be obtained.

Based on the same inventive concept, the embodiment of the present disclosure further provides a detection device, including the detection panel of any one of the above provided by the embodiment of the present disclosure. The principles for the above detection device to solve problems are similar with those of the previous detection panel. Therefore, the implementation of the detection device may refer to implementation of the previous detection panel and a repeated part is not described herein.

The embodiments of the present disclosure provide a detection panel, a manufacturing method thereof, and a detection device. The detection panel includes a base substrate, a detection circuit on the base substrate, a photoelectric conversion structure on the detection circuit and electrically connected to the detection circuit, and a bias voltage layer on the photoelectric conversion structure and electrically connected to the photoelectric conversion structure, wherein the bias voltage layer has a grid-like structure. In the present disclosure, the bias voltage layer is a grid-like structure. When gathering of static electricity on the surface of the detection panel is caused by touching the surface of the detection panel by the detector or the incomplete washing process of the detection panel, the bias voltage layer of the grid-like structure can lead the static electricity out timely, so as to avoid gathering of the static electricity on the surface of the detection panel, improve the capability of the detection panel against ESD and reduce Mura resulting from the static electricity, such that the problem of poor contact on the surface of the detection panel caused by electrostatic accumulation is improved.

Obviously, those skilled in the art can make various modifications and variations to the present disclosure without departing from the spirit and scope of the present disclosure. By doing this, if these modifications and variations to the present disclosure belong to the claims of the present disclosure and the scope of equivalent techniques thereof, the present disclosure also intends to include these modifications and variations inside.

1. A detection panel, comprising:
a base substrate;
a detection circuit on the base substrate;
a photoelectric conversion structure on the detection circuit and electrically connected to the detection circuit; and
a bias voltage layer on the photoelectric conversion structure and electrically connected to the photoelectric conversion structure;
wherein the bias voltage layer has a grid-like structure.

2. The detection panel of claim 1, wherein a material of the bias voltage layer is a transparent conductive material.

3. The detection panel of claim 2, wherein the transparent conductive material is ITO.

4. The detection panel of claim 2, further comprising:
a buffer layer between the bias voltage layer and the photoelectric conversion structure and covering the photoelectric conversion structure; and
a resin layer between the buffer layer and the bias voltage layer and in contact with the bias voltage layer.

5. The detection panel of claim 4, further comprising:
a scintillator layer on the bias voltage layer, wherein the scintillator layer is in direct contact with the resin layer through openings of the grid-like structure.

6. The detection panel of claim 1, wherein the photoelectric conversion structure comprises a first electrode, a photodiode and a second electrode stacked successively on the detection circuit, and the detection circuit comprises a thin film transistor, the first electrode is electrically connected to a drain of the thin film transistor and the second electrode is electrically connected to the bias voltage layer.

7. A detection device, comprising the detection panel of claim 1.

8. A manufacturing method of the detection panel of claim 1, comprising:
forming a detection circuit on a base substrate;
forming a photoelectric conversion structure on the detection circuit; and
forming a bias voltage layer on the photoelectric conversion structure, wherein the bias voltage layer is electrically connected to the photoelectric conversion structure, and the bias voltage layer has a grid-like structure.

9. The manufacturing method of claim 8, wherein before forming the bias voltage layer, the method further comprises:
forming a buffer layer covering the photoelectric conversion structure; and
forming a resin layer on the buffer layer, wherein the resin layer is in contact with the bias voltage layer.

10. The manufacturing method of claim 9, wherein after forming the bias voltage layer, the method further comprises:
forming a scintillator layer on the bias voltage layer, wherein the scintillator layer is in direct contact with the resin layer through openings of the grid-like structure.
